(19) United States
(12) Patent Application Publication
(10) Pub. No.: US 2011/0310328 A1
(43) Pub. Date: Dec. 22, 2011

(54) POLARIZATION DEVICE, METHOD OF MANUFACTURING THE SAME, LIQUID CRYSTAL DEVICE, AND ELECTRONIC APPARATUS

(75) Inventor: Yoshitomo Kumai, Okaya-shi (JP)

(73) Assignee: SEIKO EPSON CORPORATION, Tokyo (JP)

(21) Appl. No.: 13/158,787

(22) Filed: Jun. 13, 2011

(30) Foreign Application Priority Data
Jun. 16, 2010 (JP) 2010-136852

(51) Int. Cl. G02F 1/1335; C23C 14/28

(52) U.S. Cl. 349/62; 427/163.1; 427/595

(57) ABSTRACT

There is provided a method of manufacturing a polarization device having a plurality of metal layers provided on a substrate in a stripe shape in a plan view, and a dielectric layer provided on a surface of one metal layer among the plurality of metal layers, includes forming the dielectric layer by oxidizing a surface of one of the plurality of meal layers in an oxide gas atmosphere.

### BACKGROUND

1. Technical Field

The present invention relates to a polarization device, a method of manufacturing the polarization device, a liquid crystal device, and an electronic apparatus.

2. Related Art

As a light modulating device in various electro-optical apparatuses, a liquid crystal device has been used. As a structure of the liquid crystal device, a structure in which a liquid crystal layer is interposed between a pair of substrates oppositely disposed has been widely known. In addition, a configuration, which includes a polarization device that allows a predetermined polarized light to be incident to the liquid crystal layer, and an alignment film that controls the arrangement of liquid crystal molecules when not applying a voltage, is typical.

As the polarization device, a film-type polarization device manufactured by extending a resin film including iodine or a dichroic dye in one direction and aligning the iodine or dichroic dye in this extension direction, and a wire grid type polarization device formed by lining a nano-scaled metal fine wire on a transparent substrate are known.

The wire grid type polarization device is made from an inorganic material, such that the polarization device has the merit of a superior heat resistance, and is used in a field where heat resistance is especially necessary. For example, the polarization device is used as a polarization device for a light valve of a liquid crystal projector. As such a wire grid type polarization device, for example, there is disclosed a technique described in JP-A-10-73722.

In JP-A-10-73722, a metal lattice on a substrate is oxidized by a heat treatment and thereby an oxide film is formed on the metal lattice surface, such that it is possible to provide a polarization device having superior environment resistance. However, in a method disclosed in JP-A-10-73722, a substrate is processed at a temperature of 500° C. or higher, such that cracking or deformation of the substrate is apt to occur. In addition, the metal lattice itself is damaged by a heat expansion, and thereby dimension of the metal lattice such as height and width, which determines a characteristic of the polarization device, is changed before and after the heat treatment. Therefore, there is a problem that a polarization characteristic of the polarization device, which is entirely uniform, cannot be shown. Furthermore, there is a problem that when the temperature is raised at the time of operating the liquid crystal device, the property of the metal lattice is changed, such that the polarization characteristic is lowered.

### SUMMARY

An advantage of some aspects of the invention is to solve at least a part of the above-described problems.

According to a first aspect of the invention, there is provided a method of manufacturing a polarization device including a plurality of metal layers provided on a substrate in a stripe shape in a plan view, and a dielectric layer provided on a surface of one metal layer among the plurality of metal layers. The method includes forming the dielectric layer by oxidizing surface of the plurality of metal layers in an oxide gas atmosphere.

According to the first aspect of the invention, the surface of the metal layer is covered by a metal oxide layer having a high density, such that even when the temperature is raised at the time of operating a liquid crystal device or the like in which the polarization device is included, deterioration of the metal layer owing to oxidation or the like does not easily occur. As a result thereof, it is possible to manufacture at relatively low temperatures a polarization device whose polarization characteristic is not easily diminished.

In addition, it is preferable that the oxide gas is ozone gas.

According to this configuration, it is possible to increase the oxidation rate of the metal layer and thereby it is possible to provide a manufacturing method with a high productivity. In addition, it is possible to increase the density of the metal oxide layer and thereby it is possible to further improve oxidation resistance and abrasion resistance.

In addition, it is preferable that in the forming of the dielectric layer, the metal layer is irradiated with ultraviolet light.

According to this configuration, a decomposition reaction of ozone is promoted, and thereby it is possible to form an oxide film at a low temperature. In addition, the density of the metal oxide layer can be increased, and thereby it is possible to further improve the oxidation resistance and abrasion resistance.

In addition, it is preferable that the method further includes forming a groove in the substrate, in a region between the plurality of metal layers.

According to this configuration, it is possible to reduce an effective refraction index of a boundary face between the substrate and the metal layer, such that the reflection of the TM wave at the boundary face can be suppressed. As a result thereof, the transmittance of the TM wave is increased, and thereby it is possible to obtain a bright polarization device.

In addition, it is preferable that the plurality of metal layers is formed of a material selected from aluminum, silver, copper, chrome, titanium, nickel, tungsten, and iron, and the dielectric layer is formed of an oxide of the material selected for the metal layer.

According to this configuration, when the polarization device is used under a high temperature environment, it is possible to suppress oxidation of the metal layer, and thereby it is possible to suppress the deterioration of the polarization characteristic of the polarization device.

According to a second aspect of the invention, there is provided a projection type display apparatus including a light source; a liquid crystal electro-optical device to which light emitted from the light source is incident; a projective optical system that allows the light passed through the liquid crystal electro-optical device to be projected to a surface to be projected; and the above-described polarization device provided at at least one of between the light source and the liquid crystal electro-optical device on an optical path of the light emitted from the light source and between the liquid crystal electro-optical device and the projective optical system on an optical path of the light passed through the liquid crystal electro-optical device.

According to this configuration, the projection type display apparatus includes the polarization device having a high heat resistance, such that it is possible to suppress the deterioration of the polarization device, which is caused by oxidation or the like, even when the high-output light source is used. Therefore, it is possible to provide the projection type display apparatus that has a high reliability and a superior display characteristic.

According to a third aspect of the invention, there is provided a liquid crystal device including a liquid crystal layer interposed between a pair of substrates; and the above-described polarization device, which is interposed between at least one substrate among the pair of substrates and the liquid crystal layer.

According to this configuration, it is possible to provide a liquid crystal device including the polarization device that has a superior optical characteristic and reliability.

According to a fourth aspect of the invention, there is provided an electronic apparatus including the above-described liquid crystal device.

According to this configuration, it is possible to provide an electronic apparatus that has a superior display quality and reliability.

### BRIEF DESCRIPTION OF THE DRAWINGS

The invention will be described with reference to the accompanying drawings, wherein like numbers reference like elements.

FIGS. 1A and 1B are schematic diagrams illustrating a polarization device according to a first embodiment of the invention.

FIGS. 2A and 2B are process cross-sectional views illustrating a method of manufacturing the polarization device according to the first embodiment.

FIG. 3 is a schematic view illustrating a polarization device according to a modified example of the first embodiment.

FIG. 4 is a schematic diagram illustrating a configuration of a projector as an electronic apparatus.

FIG. 5 is a schematic diagram illustrating a configuration of a liquid crystal device.

FIG. 6 is a perspective view illustrating a configuration of a mobile phone as an electronic apparatus in which the liquid crystal device is mounted.

FIG. 7 is an SEM photograph illustrating an YZ cross-section of a reflection type polarization device.

### DESCRIPTION OF EXEMPLARY EMBODIMENTS

### First Embodiment

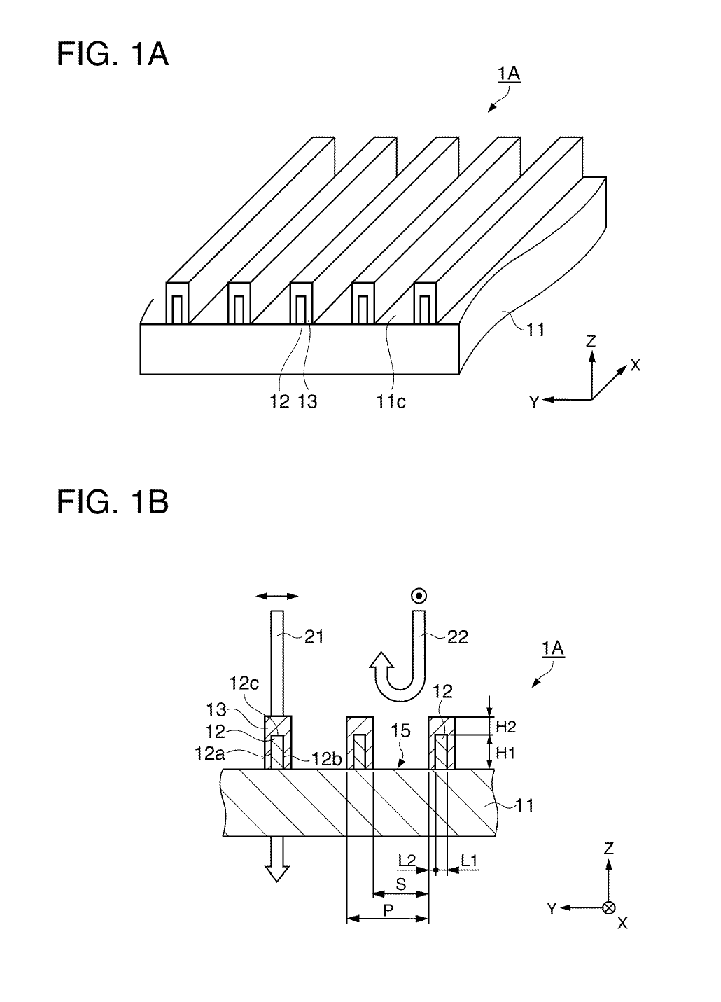

Hereinafter, a polarization device and a method of manufacturing the polarization device according to an embodiment of the invention will be described with reference to the drawings. FIGS. 1A and 1B are schematic diagrams of a polarization device 1A of this embodiment, in which FIG. 1A is a partial perspective view and FIG. 1B is a partial cross-sectional view, in which the polarization device 1A is cut out at the YZ plane.

In addition, in the following description, the XYZ orthogonal coordinate system is set and a positional relationship of each member will be described with reference to the XYZ coordinate system. At this time, a plane, which is parallel with a plane 11c of a substrate 11 provided with a metal layer 12, is set as the XY plane, and an extending direction of the metal layer 12 is set as the X-axis direction. An arrangement axis of the metal layer 12 is the Y-axis. In addition, in all of the following drawings, the scale and thickness of each component is appropriately made to be different for easy understanding of the drawings.

### Polarization Device

As shown in FIGS. 1A and 1B, the polarization device 1A includes a substrate 11, a plurality of metal layers 12 formed on the substrate 11 in a stripe shape in a plan view, and dielectric layers 13, each covering one of the metal layers 12. The dielectric layer 13 covers a first side face 12a extending in an X-axis direction of the metal layer 12, a second side face 12b opposite to the first side face 12a, and a top part 12c.

As the substrate 11, a glass substrate is used. However, the substrate 11 may be formed of a translucent material. For example, quartz, plastic, or the like may be used for the substrate. In addition, since the polarization device 1A may accumulate heat and gain a high temperature depending on a usage of the polarization device 1A, as the material of the substrate 11, glass or quartz having high heat resistance is preferable.

As a material of the metal layer 12, a material having a high reflectance with respect to light in a visible range is used. In this embodiment, as the material of the metal layer 12, aluminum is used. A metallic material such as silver, copper, chrome, titanium, nickel, tungsten, and iron may be used other than aluminum.

The dielectric layer 13 is formed on the first side face 12a, the second side face 12b, and the top part 12c of the metal layer 12. As a material of the dielectric layer 13, a material having a high optical transmittance in a visible range, for example, a dielectric material such as aluminum oxide is used. In this example, as the dielectric layer 13, an oxide of the metal layer 12 is used. As described later, the dielectric layer 13 may be formed by oxidizing the metal layer 12.

A groove portion 15 is provided between two adjacent metal layers 12. The groove portion 15 is provided with a substantially equal distance in the Y-axis direction at a cycle shorter than a wavelength of visible light. The metal layer 12 and the dielectric layer 13 are arranged in the Y-axis direction with the same cycle as each other. For example, a height H1 of the metal layer 12 is 50 to 200 nm, and a width L1 of the metal layer 12 in the Y-axis direction is 40 nm. A height H2 of the dielectric layer 13 is 10 to 100 nm, and a width L2 of the dielectric layer 13 in the Y-axis direction is 5 to 30 nm. The width L2 of the dielectric layer 13 may be called a thickness of the dielectric layer 13 at a side face of the metal layer 12. In addition, a distance S between two adjacent dielectric layers 13 (width of the groove portion 15 in the Y-axis direction) is 70 nm, and a cycle P (pitch) is 140 nm.

As described above, the polarization device 1A including the metal layer 12 and the dielectric layer 13 is configured to transmit a transverse magnetic (TM) wave 21 that is linearly polarized light vibrating in a direction (Y-axis direction) orthogonal to the extension direction of the metal layer 12 and to reflect a transverse electric (TE) wave 22 that is linearly polarized light vibrating in the extension direction (X-axis direction) of the metal layer 12.

### Method of Manufacturing Polarization Device

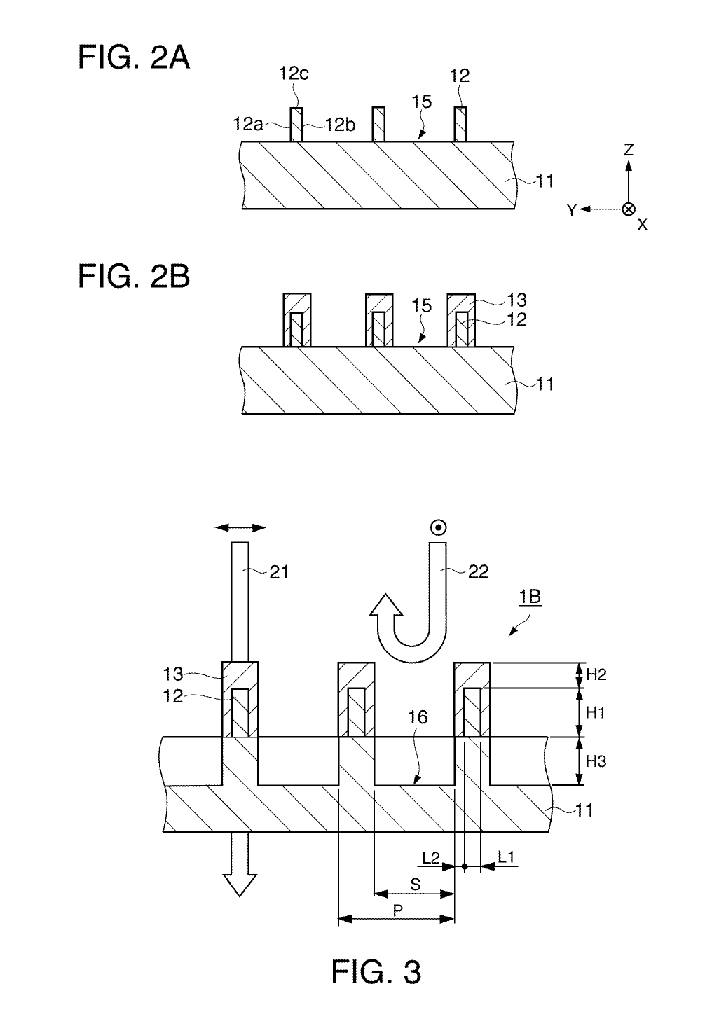

Hereinafter, a method of manufacturing the polarization device 1A of this embodiment will be described. FIGS. 2A and 2B show process diagrams illustrating a method of manufacturing the polarization device in the first embodiment. The method of manufacturing the polarization device 1A according to this embodiment includes a metal layer forming process of forming the plurality of metal layers 12 with a strip shape in a plan view on the substrate 11, and a dielectric layer forming process of forming the dielectric layer 13 on the first side face 12a, the second side face 12b, and the top part 12c of the metal layer 12. Hereinafter, description will be given with reference to the drawings.

In the process of forming the metal layer of FIG. 2A, the metal layer 12 is formed on a plane 11c of the substrate 11. Specifically, an aluminum film is formed on the substrate and a resist film is formed on the aluminum film. Subsequently, the resist film is exposed and then is developed, and thereby a stripe-shaped pattern is formed in the resist film. Subsequently, the aluminum film is etched until the plane 11c of the substrate 11 comes to appear by using the resist film as an etching mask. Subsequently, the resist film is removed, and thereby a plurality of metal layers 12 disposed in a stripe shape is formed on the substrate 11.

In the dielectric layer forming process of FIG. 2B, the dielectric layer 13 is formed on the first side face 12a, the second side face 12b, and the top part 12c of each of the metal layers 12. Specifically, the substrate 11 on which the metal layers 12 are formed is disposed in a vacuum vessel that is formed of quartz or the like and ozone gas is controlled within a range of 50 Pa to 100 Pa therein. Subsequently, the metal layers 12 are irradiated by ultraviolet light (wavelength<310 nm) from the plane 11c side of the substrate 11. The ultraviolet light is emitted by a Deep-UV lamp.

For example, an intensity of the ultraviolet light is 120 mW/cm². The ozone gas has a high absorption coefficient within a wavelength of 220 nm to 300 nm, such that as a result of an optical absorption reaction, oxygen atoms in an excited state, which have a high energy, may be generated efficiently. The excited oxygen atoms have a diffusion coefficient (activity) greater than normal oxygen atoms have, and show a high oxidation rate. In addition, an oxidized film may be formed at a low temperature lower than that in a thermal oxidation. In this process, a side, which is opposite to the plane 11c of the substrate 11, is irradiated by a halogen lamp and thereby a temperature of the substrate is increased to 150° C. Accordingly, the oxidation reaction is further promoted.

Under this environment, ozone oxidation is performed for 20 minutes, and thereby an aluminum oxidized film (dielectric layer 13) with a thickness L2 of 30 nm is formed on a surface of the metal layer 12. The thickness of the dielectric layer 13 may be appropriately selected depending on a magnitude of a phase difference applied to visible light. It is possible to manufacture the polarization device 1A through the above-described processes.

According to the manufacturing method of this embodiment, it is possible to form the oxidized film (dielectric layer 13) of the metal layer 12 at a temperature lower than that in the related art. Therefore, it is possible to decrease cracking or deformation of the substrate, and it is possible to decrease variations before and after the heat treatment in the dimensions of the metal layer 12, such as the height and the width, that determine the characteristics of the polarization device. Therefore, it is possible to increase an in-plane uniformity of the polarization characteristics of the polarization device 1A.

In addition, according to the manufacturing method of this embodiment, it is possible to cover the first side face 12a, the second side face 12b, and the top part 12c of the metal layer 12 with the dielectric layer 13 of a density higher than that in the related art. Therefore, even when the temperature is raised in use, it is possible to prevent the deterioration of the metal layer 12, which may be caused by oxidation or the like, and thereby it is possible to lower a decrease in the polarization characteristic.

Hereinafter, an operation of the polarization device 1A of this embodiment will be described.

As described above, in regard to the polarization device 1A, the metal layer 12 is formed of a material such as aluminum that has a high optical reflectance within a visible region. In addition, the dielectric layer 13 is formed of a material such as aluminum oxide that has a high optical transmittance in a visible region.

As described above, the polarization device 1A has a structure where the metal layer 12 and the dielectric layers 13 are laminated, such that it is possible to transmit the TM wave 21 that is linearly polarized light vibrating in a direction orthogonal to the extension direction of the metal layer and to reflect the TE wave 22 that is linearly polarized light vibrating in the extension direction of the metal layer.

That is to say, when the TE wave 22 incident from the dielectric layer 13 side of the substrate 11 passes through the dielectric layer 13, a phase difference is applied thereto, and the TE wave 22 is reflected from the metal layer 12 (functions as a wire grid). When the reflected TE wave 22 passes through the dielectric layer 13, a phase difference is applied thereto, and the reflected TE wave 22 is attenuated by an interference effect.

In addition, the entirety of both side faces and the top face of the metal layer 12 is covered by the dielectric layer 13 with a density higher than that in the related art, such that the deterioration of the metal layer, which may be caused by oxidation or the like is prevented, and thereby it is possible to prevent the decrease in polarization separation function. Since an area of remaining side face of the metal layer 12 is extremely small compared to the total surface area of the metal layer 12, the remaining side face of the metal layer 12 is not necessary to be covered by the dielectric layer 13, but it may be covered.

As described above, according to this embodiment, it is possible to obtain the polarization device 1A in which the polarization characteristic is not easily decreased even when a temperature is raised in use.

### Modified Example of First Embodiment

FIG. 3 shows an explanatory diagram of a polarization device 1B according to a modified example of the first embodiment. The polarization device 1B is partially common with the polarization device 1P, of the first embodiment. There is a difference in that a region 16, which has a refraction index lower than that of the substrate 11, is formed between the metal layers 12.

As shown in FIG. 3, the polarization device 1B has a region 16 having a refraction index lower than that of the substrate 11 between two adjacent metal layers 12, in addition to the configuration of the polarization device 1A.

The region 16 is formed by removing the substrate 11 exposed between the two adjacent metal layers 12 through a dry etching or the like. A digging depth H3 is substantially the same as a height H1 of the metal layer 12.

According to this configuration, it is possible to reduce an effective refraction index of a boundary region between the substrate and the metal layer, such that the reflection of the TM wave 21 at the boundary region is suppressed and as a result, it is possible to increase the transmittance of the TM wave 21.

### Projection Type Display Apparatus

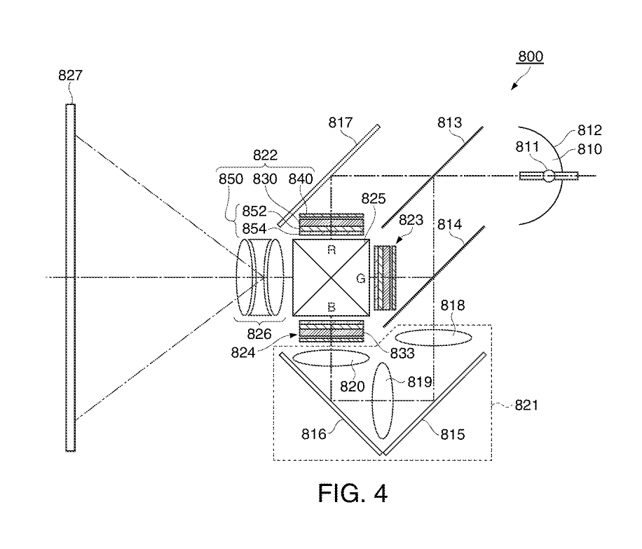

Hereinafter, embodiments of an electronic apparatus of the invention will be described. A projector 800, which is shown in FIG. 4, includes a light source 810, dichroic mirrors 813 and 814, reflective mirrors 815, 816, and 817, an incident lens 818, a relay lens 819, an emission lens 820, light modulating units 822, 823 and 824, a cross dichroic prism 825, and a projection lens 826.

The light source 810 includes a lamp 811 such as a metal halide, and a reflector 812 that reflects light of the lamp. In addition, as the light source 810, a ultrahigh pressure mercury lamp, a flash mercury lamp, a high pressure mercury lamp, a Deep UV lamp, a xenon lamp, a xenon flash lamp or the like may be used other than the metal halide.

The dichroic mirror 813 transmits red light included in white light emitted from the light source 810 and reflects blue light and green light. The transmitted red light is reflected from the reflective mirror 817 and is incident to the light modulating unit 822 for red light. In addition, among the blue light and the green light reflected from the dichroic mirror 813, the green light is reflected from the dichroic mirror 814 and is incident to the light modulating unit 823 for green light. The blue light passes through the dichroic mirror 814 and is incident to the light modulating unit 824 via a relay optical system 821 including the incident lens 818 that is provided to prevent light loss caused by along optical path, the relay lens 819, and the emission lens 820.

In the light modulating units 822 to 824, an incident side polarization device 840 and an emission side polarization device section 850 are disposed with a liquid crystal light valve 830 interposed therebetween. The incident side polarization device 840 is provided on a light path of light emitted from the light source 810 and between the light source 810 and the liquid crystal light valve 830. In addition, the emission side polarization device section 850 is provided on a light path of light passed through the liquid crystal light valve 830 and between the liquid crystal light valve 830 and the projection lens 826. The incident side polarization device 840 and the emission side polarization device section 850 are disposed in a manner where the transmission axes thereof are orthogonal to each other (Cross-Nicole arrangement).

The incident side polarization device 840 is a reflection type polarization device described in the first embodiment and reflects light in a vibration direction orthogonal to the transmission axis.

On the other hand, the emission side polarization device section 850 includes a first polarization device (pre-polarization plate, synonymous with a pre-polarizer) 852, and a second polarization device 854. As the first polarization device 852, a polarization device, which is configured by adding a light absorbing layer to the polarization device according to the embodiment of the invention, is used. In addition, the second polarization device 854 is a polarization device formed of an organic material as a formation material. The first and second polarization devices 852 and 854 are absorption type polarization device, respectively, and the first and second polarization devices 852 and 854 absorb light in cooperation with each other.

In general, an absorption type polarization device, which is formed of an organic material, is apt to be deteriorated due to heat, such that it is difficult to be used as a polarization unit of a large output projector in which a high brightness is necessary. However, in the projector 800 according to the embodiment of the invention, the first polarization device 852, which is formed of an inorganic material having high heat resistance, is disposed between the second polarization device 854 and the liquid crystal light valve 830, and the first and second polarization devices 852 and 854 absorb light in cooperation with each other. Therefore, it is possible to suppress the deterioration of the second polarization device 854 formed of an organic material.

Three colored light beams modulated by respective light modulating units 822 to 824 are incident to a cross dichroic prism 825. The cross dichroic prism 825 includes four right angle prism bonded to each other, and at a boundary face thereof, a dielectric multi-layered film reflecting red light and a dielectric multi-layered film reflecting blue light are formed in an X-shape. The three colored light beams are synthesized by these dielectric multi-layered films and light representing a color image is formed. The synthesized light is projected on a screen 827 by a projection lens 826 that is a projective optical system and the image is enlarged and displayed.

The projector 800 with the above-described configuration uses the polarization device according to the embodiment of the invention, whereby it is possible to suppress the deterioration of the polarization device even when the high-output light source is used. Therefore, it is possible to provide the projector 800 that has a high reliability and a superior display characteristic.

### Liquid Crystal Device

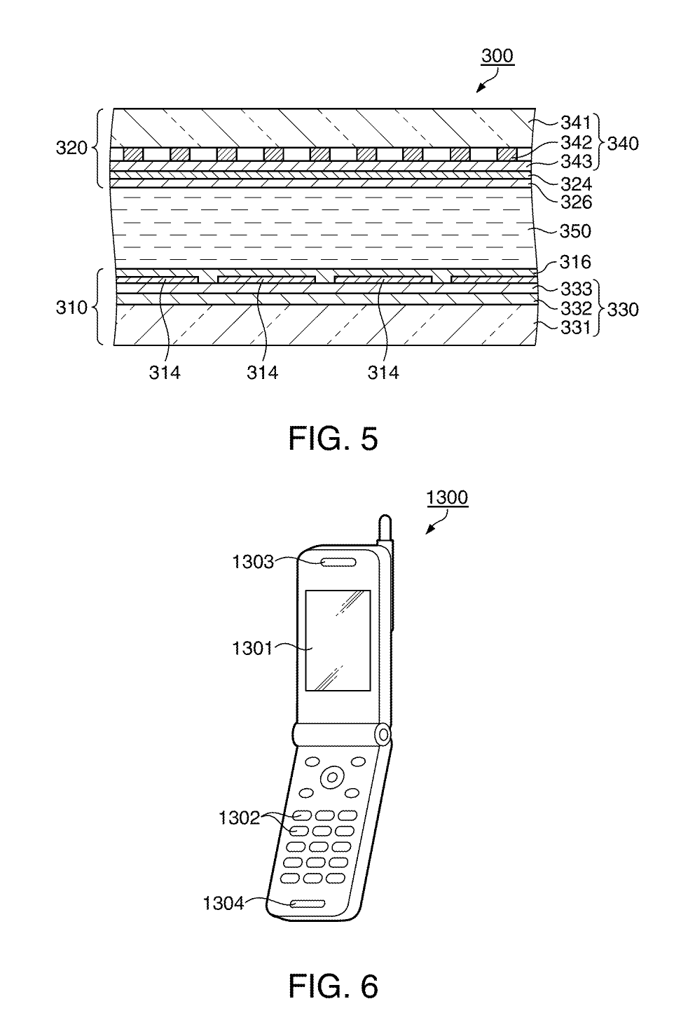

FIG. 5 shows a cross-sectional schematic diagram illustrating an example of a liquid crystal device 300 including the polarization device according to the embodiment of the invention. The liquid crystal device 300 of this embodiment has a configuration where a liquid crystal layer 350 is interposed between an element substrate 310 and a counter substrate 320.

The element substrate 310 includes a polarization device 330, and the counter substrate 320 includes a polarization device 340. The polarization device 330 and the polarization device 340 are the above-described polarization devices of the first embodiment.

The polarization device 330 includes a substrate main body 331, a metal layer 332, and a protective film 333, and the polarization device 340 includes a substrate main body 341, a metal layer 342, and a protective film 343. However, the dielectric layers 13, which include the metal layers 332 and 342, respectively, are not shown in FIG. 5. In this embodiment, the substrate main bodies 331 and 341 are substrates of the polarization device and also serve as substrates for the liquid crystal device. In addition, the metal layers 332 and 342 are disposed to intersect each other. In any of the polarization devices, the metal layer is disposed at an inner face side (liquid crystal layer 350 side).

At the liquid crystal layer 350 side of the polarization device 330, a pixel electrode 314, and an interconnection and a TFT device (not shown), and an alignment film 316 are provided. Similarly, at an inner face side of the polarization device 340, a common electrode 324 and an alignment film 326 are provided.

In the liquid crystal device configured as described above, the substrate main bodies 331 and 341 combine the functions of the substrate for the liquid crystal device and the substrate for the polarization device, whereby it is possible to reduce the number of parts. Therefore, the entirety of the apparatus can be made to be slim, and thereby the function of the liquid crystal device 300 can be improved. Furthermore, the apparatus structure is simple, such that the manufacturing thereof is easy and thereby a reduction in costs may be realized.

### Electronic Apparatus

Hereinafter, another embodiment related to an electronic apparatus of the invention will be described. FIG. 6 shows a perspective view illustrating an example of the electronic apparatus using the liquid crystal device shown in FIG. 5. A mobile phone (electronic apparatus) 1300 shown in FIG. 6 includes the liquid crystal device as a small-sized display section 1301, a plurality of operation buttons 1302, an earpiece 1303, and a mouthpiece 1304. Therefore, it is possible to provide the mobile phone 1300 including a display section that has superior reliability and can display in high quality.

In addition, the liquid crystal device may be suitably used as an image display section of an electronic book, a personal computer, a digital still camera, a liquid crystal television, a projector, a view finder type or monitor direct vision type video tape recorder, a car navigation apparatus, a pager, an electronic pocket book, a calculator, a word processor, a work station, a television phone, a POS terminal, an apparatus having a touch panel, or the like, other than the mobile phone.

The invention is not limited to the above-described embodiment and various changes may be made without departing from the scope of the invention.

### Test Production Verification of Polarization Device and Evaluation of Reliability

For confirming the effect of the invention, a polarization device was manufactured and optical characteristics after a reliability test were evaluated.

In the evaluation, it was assumed that the polarization device of the invention is applied as a polarization device for a light valve of a liquid crystal projector. The polarization device of the invention is formed of an inorganic material and has a high heat resistance, and thereby can be applied as an incident side polarization device of a liquid crystal projector having the high output light source described above.

In the incident side polarization device as described above, it is necessary to have a high transmittance with respect to TM light, and to have a high reflectance and a low transmittance with respect to TE light. Specifically, when the transmittance I(TM) of TM light is greater than 80%, and the transmittance I(TE) of the TE light is less than 1%, there is no problem in use, and it is more preferable that the contrast defined by I(TM)/I(TE) is 100 or more. In addition, a time where the transmittance of the TE light is changed by 10% from an initial value is defined as a product lifespan.

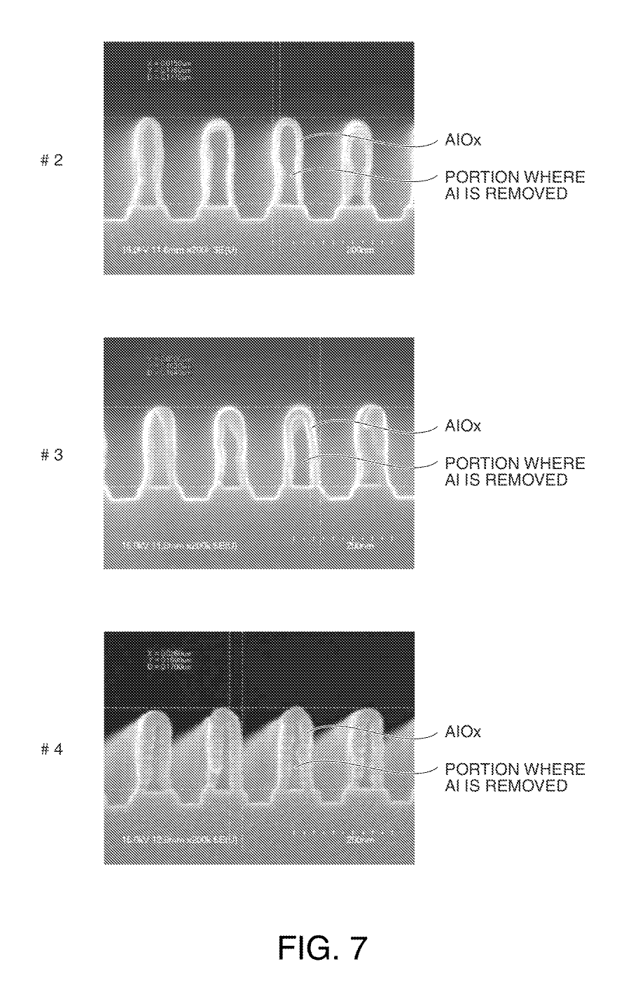

Test production levels are shown in Table 1. A width L2 of the dielectric layer 13 is controlled by the processing time of the above-described ozone oxidation. In each sample, the following are common. The height H1 of aluminum (metal layer 12): 160 nm, the width S of the groove portion 15: 70 nm, and the cycle P of the dielectric layer 13 (or metal layer 12): 140 nm. Sample No. 1 is a comparative example where the ozone processing is not performed, and a naturally oxidized film is formed on a surface of the metal layer 12. The naturally oxidized film is different from the dielectric layer 13 according to the embodiment of the invention, but in Table 1, a thickness of the naturally oxidized film of Sample No. 1 is shown as a width L2 of a dielectric layer for convenience. FIG. 7 shows SEM observation results of Nos. 2, 3, and 4. In the observation, in order to measure a width of the dielectric layer, the aluminum was dissolved to expose the dielectric layer 13.

TABLE 1

| | Width L1 of | Width L2 of |
|---|---|---|
| | metal layer | dielectric layer |
| Sample No. | (nm) | (nm) |
| 1 | 60 | 5 |
| 2 | 40 | 15 |
| 3 | 30 | 20 |
| 4 | 18 | 26 |

With respect to the sample manufactured as described above, a reliability test was performed at 300° C. under the atmosphere environment. Next, a lifespan where transmittance of the TE light was changed by 10% from an initial value and a magnification of extended lifespan with No. 1 given as a reference were shown in Table 2. In the measurement, a spectral photometer U-4100 (trade name; manufactured by Hitachi High-Technologies Corporation) was used.

TABLE 2

| | | Magnification of |
|---|---|---|
| Sample No. | Lifespan (hr) | extended lifespan |
| 1 | 3.2 | 1.0 |
| 2 | 110.0 | 34.3 |
| 3 | 230.0 | 71.7 |
| 4 | 123.3 | 38.5 |

From the results, the lifespan is significantly increased by the formation of the dielectric layer, and No. 3 (width of the dielectric layer is 20 nm) shows the highest value in the magnification of the extended lifespan. Here, the formed dielectric layer 13 (aluminum oxide) has a lattice constant greater than that of the metal layer 12 (aluminum) by substantially 20%. Therefore, like the case of No. 4, it is considered that when the metal layer is converted into the dielectric layer 13 by 40% or more with respect to the width (60 nm) of the metal layer 12 before the ozone processing, crystal defects occur according to the change in volume, and as a result thereof, oxygen is introduced by using the crystal defects as an introduction path and thereby the oxidation is progressed. From the above description, it could be seen that in the case of the test-produced polarization device, when the width L2 of the dielectric layer 13 was controlled in a range of 25% to 40% with respect to the width of the metal layer 12 before the ozone processing, it was possible to manufacture the polarization device having the longest product lifespan.

From the results, it was confirmed that the reflection type polarization device having the configuration of the invention had superior optical characteristics and the configuration of the invention was effective for solving the problems.

The entire disclosure of Japanese Patent Application No. 2010-136852, filed on Jun. 16, 2010 is expressly incorporated by reference herein.

What is claimed is:

1. A method of manufacturing a polarization device including a plurality of metal layers provided on a substrate in a stripe shape in a plan view, and a dielectric layer provided on a surface of one metal layer among the plurality of metal layers, the method comprising:
forming the dielectric layer by oxidizing a surface of one of the plurality of metal layers in an oxide gas atmosphere.

2. The method according to claim 1,
wherein the oxide gas is ozone gas.

3. The method according to claim 1,
wherein in the forming of the dielectric layer, the plurality of metal layers is irradiated with ultraviolet light.

4. The method according to claim 1, further comprising:
forming a groove in the substrate, in a region between the plurality of metal layers.

5. The method according to claim 1,
wherein the plurality of metal layers is formed of a material selected from aluminum, silver, copper, chrome, titanium, nickel, tungsten, and iron, and
the dielectric layer is formed of an oxide of the material selected for the plurality of metal layers.

6. A projection type display apparatus, comprising:
a light source;
a liquid crystal electro-optical device to which light emitted from the light source is incident;
a projective optical system that allows the light passed through the liquid crystal electro-optical device to be projected to a surface to be projected; and
the polarization device manufactured by the method according to claim 1, which is provided at at least one of between the light source and the liquid crystal electro-optical device on an optical path of the light emitted from the light source and between the liquid crystal electro-optical device and the projective optical system on an optical path of the light passed through the liquid crystal electro-optical device.

7. A projection type display apparatus, comprising:
a light source;
a liquid crystal electro-optical device to which light emitted from the light source is incident;
a projective optical system that allows the light passed through the liquid crystal electro-optical device to be projected to a surface to be projected; and
the polarization device manufactured by the method according to claim 2, which is provided at at least one of between the light source and the liquid crystal electro-optical device on an optical path of the light emitted from the light source and between the liquid crystal electro-optical device and the projective optical system on an optical path of the light passed through the liquid crystal electro-optical device.

8. A projection type display apparatus, comprising:
a light source;
a liquid crystal electro-optical device to which light emitted from the light source is incident;
a projective optical system that allows the light passed through the liquid crystal electro-optical device to be projected to a surface to be projected; and
the polarization device manufactured by the method according to claim 3, which is provided at at least one of between the light source and the liquid crystal electro-optical device on an optical path of the light emitted from the light source and between the liquid crystal electro-optical device and the projective optical system on an optical path of the light passed through the liquid crystal electro-optical device.

9. A projection type display apparatus, comprising:
a light source;
a liquid crystal electro-optical device to which light emitted from the light source is incident;
a projective optical system that allows the light passed through the liquid crystal electro-optical device to be projected to a surface to be projected; and
the polarization device manufactured by the method according to claim 4, which is provided at at least one of between the light source and the liquid crystal electro-optical device on an optical path of the light emitted from the light source and between the liquid crystal electro-optical device and the projective optical system on an optical path of the light passed through the liquid crystal electro-optical device.

10. A projection type display apparatus, comprising:
a light source;
a liquid crystal electro-optical device to which light emitted from the light source is incident;
a projective optical system that allows the light passed through the liquid crystal electro-optical device to be projected to a surface to be projected; and
the polarization device manufactured by the method according to claim 5, which is provided at at least one of between the light source and the liquid crystal electro-optical device on an optical path of the light emitted from the light source and between the liquid crystal electro-optical device and the projective optical system on an optical path of the light passed through the liquid crystal electro-optical device.

11. A liquid crystal device, comprising:
a liquid crystal layer interposed between a pair of substrates; and
the polarization device manufactured by the method according to claim 1, which is interposed between at least one substrate among the pair of substrates and the liquid crystal layer.

12. A liquid crystal device, comprising:
a liquid crystal layer interposed between a pair of substrates; and
the polarization device manufactured by the method according to claim 2, which is interposed between at least one substrate among the pair of substrates and the liquid crystal layer.

13. A liquid crystal device, comprising:
a liquid crystal layer interposed between a pair of substrates; and
the polarization device manufactured by the method according to claim 3, which is interposed between at least one substrate among the pair of substrates and the liquid crystal layer.

14. A liquid crystal device, comprising:
a liquid crystal layer interposed between a pair of substrates; and
the polarization device manufactured by the method according to claim 4, which is interposed between at least one substrate among the pair of substrates and the liquid crystal layer.

15. A liquid crystal device, comprising:
a liquid crystal layer interposed between a pair of substrates; and
the polarization device manufactured by the method according to claim 5, which is interposed between at least one substrate among the pair of substrates and the liquid crystal layer.

16. An electronic apparatus comprising:
the liquid crystal device according to claim 11.

17. An electronic apparatus comprising:
the liquid crystal device according to claim 12.

18. An electronic apparatus comprising:
the liquid crystal device according to claim 13.

19. An electronic apparatus comprising:
the liquid crystal device according to claim 14.

20. An electronic apparatus comprising:
the liquid crystal device according to claim 15.
